(19) United States
(12) Patent Application Publication
(10) Pub. No.: US 2026/0293777 A1
(43) Pub. Date: Sep. 24, 2026

(54) APPARATUS INCLUDING STACKING INTERPOSER AND METHODS OF MANUFACTURING THE SAME

(71) Applicant: Micron Technology, Inc., Boise, ID (US)

(72) Inventors: Gang Zhao, Boise, ID (US); Po Yu Chen, Taichung (TW); David K. Ovard, Meridian, ID (US); Timothy M. Hollis, Meridian, ID (US)

(21) Appl. No.: 19/575,170

(22) Filed: Mar. 23, 2026

Related U.S. Application Data
(60) Provisional application No. 63/776,954, filed on Mar. 24, 2025.

(51) Int. Cl. H10W 90/22; H10W 70/05; H10W 70/60; H10W 70/63; H10W 90/00

(52) U.S. Cl. CPC H10W 90/22; H10W 70/095; H10W 70/611; H10W 70/635; H10W 90/701; H10W 90/724; H10W 90/794

(57) ABSTRACT

An apparatus includes a stacking interposer configured to support dies attached to top and bottom surfaces thereof to form a subassembly. The stacking interposer includes internal connections that couple wirebonding pads on a top side thereof to the dies attached on the top and bottom surfaces. The subassembly may be stacked with one or more matching subassemblies, and bond wires connect the wirebonding pads on each of the subassemblies, thereby the dies attached to each of the interposers, to corresponding locations on a packaging substrate.

### CROSS-REFERENCE TO RELATED APPLICATION(S)

The present application claims priority to U.S. Provisional Patent Application No. 63/776,954, filed Mar. 24, 2025, the disclosure of which is incorporated herein by reference in its entirety.

### TECHNICAL FIELD

The present technology is directed to apparatuses, such as semiconductor devices including memory, and several embodiments are directed to semiconductor devices that include one or more stacking interposers.

### BACKGROUND

The current trend in semiconductor fabrication is to manufacture smaller and faster devices with a higher density of components for computers, cell phones, pagers, personal digital assistants, and many other products. Additionally, the device manufacturers are faced with persisting demand for lower prices. Accordingly, circuit designs and components that accommodate the higher density along with the lower costs are ideal. Moreover, the industry is demanding increase in power conservation and efficiency.

### BRIEF DESCRIPTION OF THE DRAWINGS

FIG. 1A is a cross-sectional view of a first package.

FIG. 1B is a cross-sectional view of a second package.

FIG. 2A is a cross-sectional view of a first package including stacking interposers in accordance with embodiments of the technology.

FIG. 2B is a top view of a stacking interposer in accordance with embodiments of the technology.

FIG. 2C is a bottom view of the stacking interposer in accordance with embodiments of the technology.

FIG. 3A is a cross-sectional view of a second package including stacking interposers in accordance with embodiments of the technology.

FIG. 3B is a top view of a stacking interposer in accordance with embodiments of the technology.

FIG. 3C is a bottom view of the stacking interposer in accordance with embodiments of the technology.

FIG. 4 is a flow diagram illustrating an example method of manufacturing an apparatus in accordance with an embodiment of the present technology.

FIG. 5 is a schematic view of a system that includes an apparatus configured in accordance with embodiments of the present technology.

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

Several embodiments of semiconductor devices, packages, and/or assemblies in accordance with the present technology can include a stacking interposer (e.g., semiconductor interposer, a substrate interposer, a printed circuit board (PCB), etc.) configured to be disposed between and attached to semiconductor dies. In other words, the stacking interposer can have (1) a top surface with a top die (e.g., a memory die, such as a Dynamic Random-Access Memory (DRAM) die, Magnetoresistive Random-Access Memory (MRAM), NAND Flash memory, and/or the like) mounted or bonded thereon and (2) a bottom surface with a bottom die mounted or bonded thereon. The stacking interposer can have wirebond pads on peripheral portions on the top surface. A subset of the wirebond pads can be coupled to a redistribution layer in the stacking interposer that electrically couples the corresponding wirebonds to the top die. A remainder of the wirebond pads can be coupled to a separate redistribution layer and vias (e.g., Through Silicon Vias (TSVs)) in the stacking interposer that electrically couples the corresponding wirebonds to the bottom die.

The stacking interposer can use the internal RDLs and the vias to laterally route signals, including power and ground, and the dies can have circuits placed closer to the bond/bump pads, thereby reducing the internal path for the corresponding signal (e.g., power and ground) within the dies. Such use of the stacking interposer to route the power and ground network therein instead of within the dies can reduce (by, e.g., 80% or more) the voltage drop (IR drop) and ground bounce. The stacking interposer can include wider/thicker internal connections (e.g., traces) for cheaper cost than placing the corresponding connections within the die. For power connections, the stacking interposer can reduce the IR voltage drop in comparison to the die-internal routing. Moreover, placing the lateral routing in the stacking interposer can free up space/area in the dies, thereby allowing the dies to have more room for other signal routing and functional circuits.

Additionally, the stacking interposer can remove the need for spacers that are typically used to create vertical separations for loops/peaks of the wirebonds. Thus, the stacking interposer can reduce the overall height of a resulting die stack in comparison to stacks that utilize the spacers. For example, in 16-die stacks, the stacking interposers can provide over 20% reduction in the overall height.

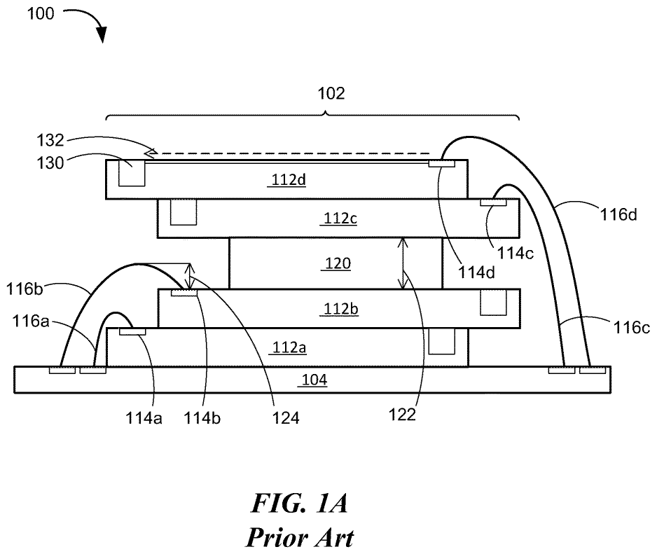

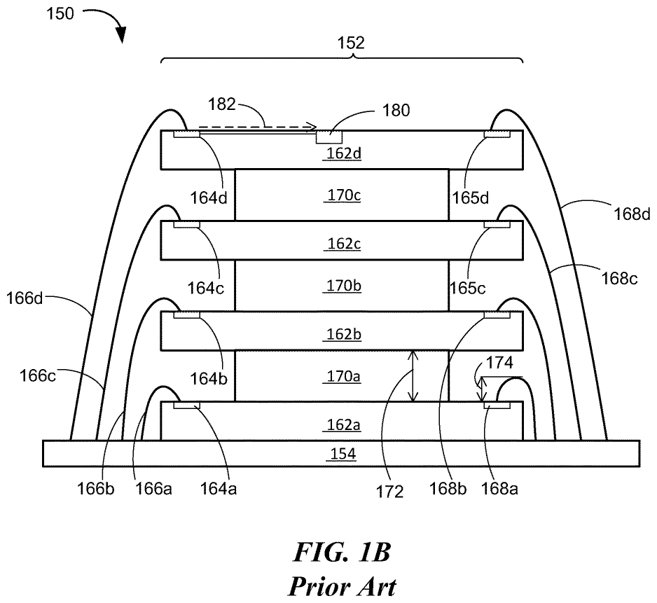

For comparison purposes, FIG. 1A is a cross-sectional view of a first package 100. The first package 100 is a type of conventional multi-chip package. The first package 100 includes a die stack 102 mounted on a substrate 104. The die stack 102 includes multiple dies, such as dies 112a-112d as shown in FIG. 1A. Each of the dies 112a-112d includes die-side pads 114a-114d, respectively, that are configured to attach to corresponding bondwires 116a-116d. In other words, the die 112a includes a set of die-side pads 114a that attach to bondwires 116a. Likewise, the die 112b includes a set of die-side pads 114b that attach to bondwires 116b, and so forth. The opposite ends of the bondwires 116a-116d are attached to substrate-side pads on the substrate 104. Accordingly, the die stack 102 communicates with external circuitry through the bondwires 116a-116d and the connections provided within or through the substrate 104.

To accommodate the use of the bondwires, the dies 112a-112d have active sides thereof facing up (e.g., away from the substrate 104). Also, the die-side pads 114a-114d are located on the active sides.

The first package 100 includes the dies 112a-112d having the die-side pads 114a-114d on one side. In other words, the die-side pads are closer to one peripheral edge than an opposing peripheral edge of the die. Moreover, a first half of the dies 112a-112d are arranged with the pads on one side, and a remainder of the dies 112a-112d are arranged with the pads on the opposite side. The first package 100 includes a spacer 120 between the rotated halves. Moreover, within each of the halves, the dies are positioned offset along a lateral direction, thereby not covering and exposing the wirebond pads.

As illustrated in FIG. 1, the first package 100 is a four-die package with a first die 112a mounted directly on the substrate 104 with the active side of the first die 112a facing away from the substrate 104. A second die 112b is mounted to the active side of the first die 112a, and an active side of the second die 112b also faces away from the substrate 104. Both the first die 112a and the second die 112b have the die-side pads 114a and 114b on the left side of the first package 100. The second die 112b is offset to the right relative to the first die 112a, thereby not covering and exposing the first die-side pad 114a of the first die 112a.

The spacer 120 is attached over the second die 112b. The spacer 120 has a thickness 122 that is greater than a maximum loop height 124 of the wirebonds (e.g., the wirebond 116b). To connect to the upward facing wirebond pads, the bondwires must extend up above the corresponding pads and then bend and extend downward to contact the wirebond pad. The maximum loop height 124 represents a maximum height corresponding to the bend of the wirebond as measured from a top surface of a corresponding bondpad. Thus, the thickness of the spacer 120 must be greater than the maximum loop height 124 such that the bondwire remains separate from the overhang created by the next die (e.g., the third die 112c).

The second half of the four dies are attached over the spacer 120. The third die 112c (the backside thereof) is directly attached to a top of the spacer 120, and the fourth die 112d is attached to the active side of the third die 112c. The third die 112c and the fourth die 112d are rotated 180 degrees about a vertical axis relative to the first die 112a and the second die 112b. Accordingly, the third die 112c and the fourth die 112d have the corresponding die-side pads 114c and 114d on the right side of the first package 100. Also, to maintain the third die-side pad 114c, the fourth die 112d is offset to the left from the third die 112c.

When the dies have wirebond pads on one side, a farthest circuit 130 communicatively coupled to the die would be on the opposing side of the die. The internal connection, such as a redistribution layer (RDL), has a relatively high resistance due to the long routing distance from the die-side pads 114a-114d to the farthest circuit 130. The high resistance causes an elevated internal voltage (IR) drop 132 from the die-side pads 114a-114d to the farthest circuit 130. The IR drop for the single-sided dies effectively correspond to the corresponding lateral dimension of the die.

Also, for comparison purposes, FIG. 1B is a cross-sectional view of a second package 150. The second package 150 has wirebond pads on multiple sides, including opposing sides, to reduce the distance for the farthest circuit and the corresponding IR drop. Similar to the first package 100 of FIG. 1A, the second package 150 is illustrated as a four-die package having a die stack 152 mounted over a substrate 154. The die stack 152 includes dies 162a-162d.

The die stack 152 includes dies 162a-162d. Each of the dies 162a-162d has (1) a corresponding one of a first die-side pad 164a-164d on one side and (2) a corresponding one of a second die-side pad 165a-165d on the opposing side. For example, a first die 162a has a first die-side pad 164a on the left side and a second die-side pad 165a on the right side. A second die 162b has a first die-side pad 164b on the left side and a second die-side pad 165b on the right side, and so forth.

Since the dies 162a-162d have wirebonding pads on opposing sides, the wirebonding pads cannot be exposed through laterally offsetting the stacked dies. Accordingly, the peripheral edges of the dies 162a-162d are aligned to a vertical line, and spacers 170a-170c are disposed between adjacent pairs of the dies 162a-162d. In other words, a spacer 170a is disposed between and attached to the first die 162a and the second die 162b, a spacer 170b is disposed between and attached to the second die 162b and a third die 162c, and a spacer 170c is disposed between and attached to the third die 162c and the fourth die 164d. Each of the spacers 170a-170c has a thickness 172 that is greater than a maximum loop height 174. The relationship between the thickness 172 and the maximum loop height 174 is the same as the relationship described above for the thickness 122 and the maximum loop height 124 illustrated in FIG. 1A.

Based on the vertical spacing provided by the spacers 170a-170c, a first set of bondwires 166a-166d are connected to the corresponding ones of the first die-side pads 164a-164d. A second set of bondwires 168a-168 are connected to the corresponding ones of the second die-side pads 165a-165d.

Having the bondwire pads on opposing sides places farthest circuit 180 at a center portion of the die. Accordingly, the power and ground path has a length that corresponds to a half of a lateral dimension of the die. Thus, an internal IR drop 182 for the second package 150 is less than the internal IR drop 132 of FIG. 1A for the first package 100. However, the second package 150 requires more spacers (e.g., two more spacers 170) than the first package 100. Thus, the second package 150 has a higher overall height than that of the first package 100.

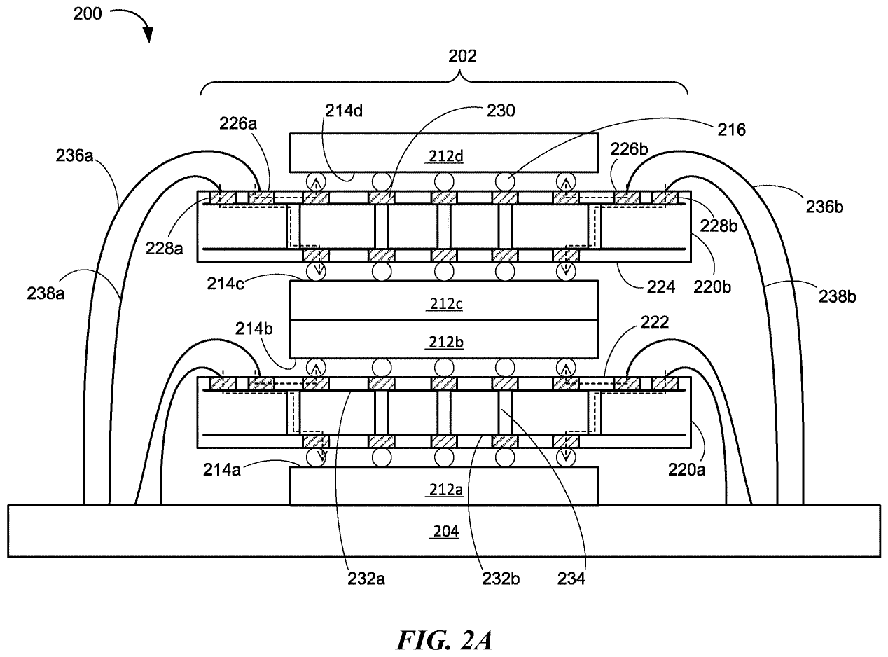

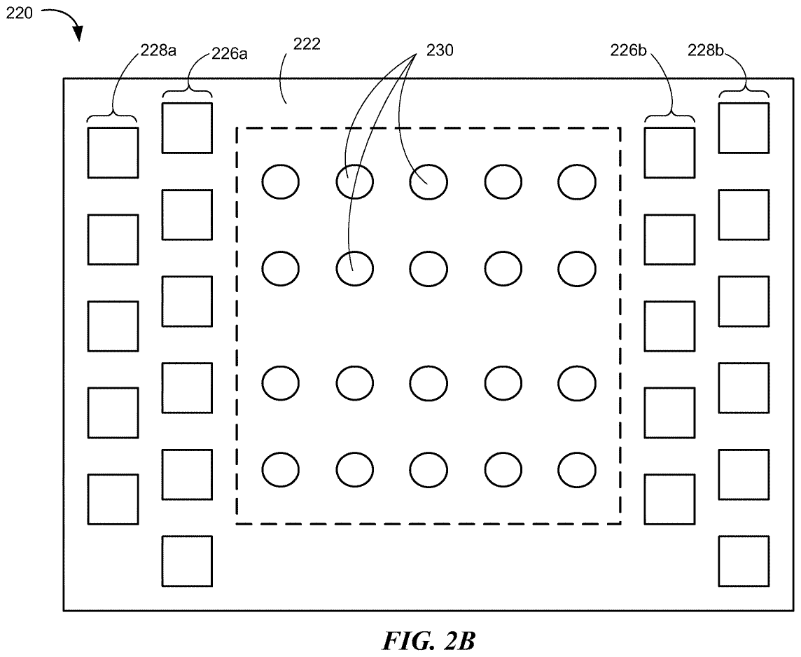

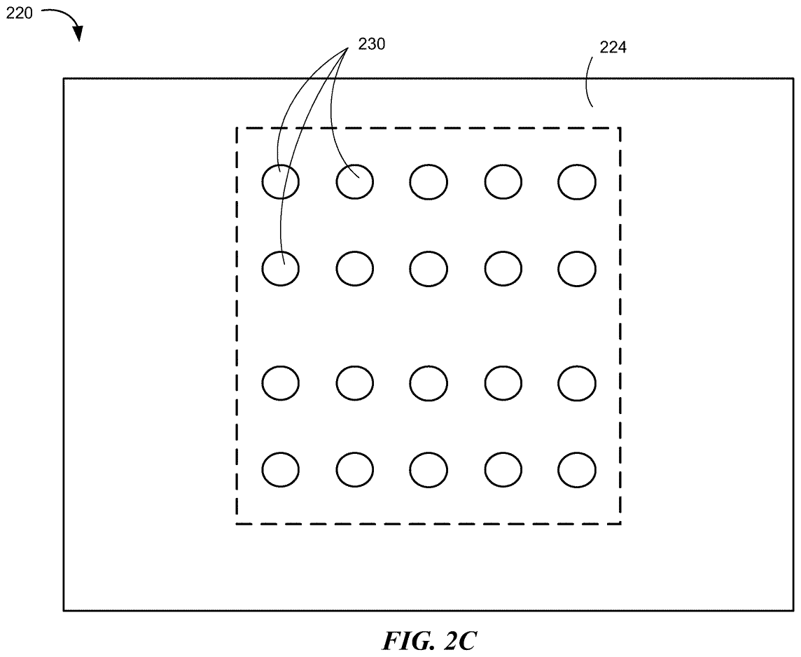

In contrast to such conventional approaches, embodiments of the present technology include one or more stacking interposers that reduce the IR drop without the height increase of the second package 150. Illustrating a first example of the stacking interposers, FIG. 2A is a cross-sectional view of a first package 200 including stacking interposers 220 in accordance with embodiments of the technology. The first package 200 can include a die stack 202 mounted over a substrate 204. The package 200 can be a four-die package with the die stack 202 including dies 212a-212d.

Each of the stacking interposers 220 can include silicon, glass, ceramic, organic, or other types of interposers that are configured to support and route signals to and from dies mounted on opposing surfaces thereof. Thus, each of the stacking interposers 220 can be disposed between and attached to active sides of an adjacent or a facing pair of dies. For example, a first stacking interposer 220a can be disposed between and attached to a first die 212a and a second die 212b. The first die 212a can have its active side 214a oriented upward and facing a bottom side 224 of the first stacking interposer 220a. A backside of the first die 212a can be mounted on the substrate 204. The second die 212b can be flipped relative to the first die 212a. Accordingly, the second die 212b can have its active side 214b oriented downward and facing a top side 222 of the first stacking interposer 220a. The first die 212a and the second die 212b can be attached to the stacking interposer 220a (e.g., to bump pads 230 thereon) through die connectors 216, such as solder bumps, micro bumps, pillars, and/or the like.

The first die 212a, the first stack interposer 220a, and the second die 212b can correspond to a first subassembly. The package 200 can include a second subassembly of a third die 212c, a second stack interposer 220b, and a fourth die 212d attached over the first subassembly. The second stacking interposer 220b can be disposed between and attached to the third die 212c and the fourth die 212d.

The third die 212c can have its backside attached directly to the backside of the second die 212b. An active side 214c of the third die 212c can be oriented upward and facing the bottom side 224 of the second stack interposer 220b. The fourth die 212d can be flipped relative to the third die 212c. Accordingly, the fourth die 212d can have its active side 214d oriented downward and facing the top side 222 of the second stacking interposer 220b. Like the first subassembly, the third die 212c and the fourth die 212d can be attached to the stacking interposer 220b (e.g., to the bump pads 230 thereon) through the die connectors 216.

Each of the stacking interposers 220 can have one set of wirebond pads on one side and another set of wirebond pads on the opposite side for each of the dies attached on the stacking interposer 220. For example, the first stacking interposer 220a can have (1) a set of top-die first pads 226a and a set of bottom-die first pads 228a on the left portion of the interposer and (2) a set of top-die second pads 226b and a set of bottom-die first pads 228b on the right portion of the interposer. The top-die first pads 226a and the top-die second pads 226b can be for communicating signals to and from the second die 212b attached on the top side of the first interposer 220a. The bottom-die first pads 228a and the bottom-die second pads 228b can be for communicating signals to and from the first die 212a attached on the bottom side of the first interposer 220a.

Likewise, the second stacking interposer 220b can have on its top side 222 (1) the top-die first pads 226a and the bottom-die first pads 228a on the left side and (2) the top-die second pads 228b and the bottom-die second pads 228b on the right side. The top-die first pads 226a and the top-die second pads 226b can be configured to communicate signals to and from the fourth die 212d attached on the top, and the bottom-die first pads 228a and the bottom-die second pads 228b can be configured to communicate signals to and from the third die 212c attached to the bottom side of the interposer. Thus, for each/both of the attached dies, the stacking interposer 220 can have wirebonding pads on the opposing sides of the dies.

The wirebonds can be coupled to one or more RDLs and vertical paths within the stacking interposers 220. For example, the stacking interposers 220 can each have (1) a top-side RDL 232a located at the top side 222 or between the top side 222 and a midpoint of the interposers and (2) a bottom-side RDL 232b located at the bottom side 224 or between the bottom side 224 and the midpoint. The top-side RDL 232a can be configured to communicatively couple to the bump pads 230 for the die attached on the top-side. The top-side RDL 232a can further be configured to communicatively couple to the wirebond pads (e.g., the first and second pads for both top-side and bottom-side dies). Thus, the top-side RDL 232a can include interposer traces or other lateral connections that electrically couple the top-die first pads 226a and the top-die second pads 228b to the die attached on the top side (e.g., the second die 212b for the first interposer 220a and the fourth die 212d for the second interposer 220b).

Some of the connections in the top-side RDL 232a can be connected to the bottom-die first pads 228a and the bottom-die second pads 228b and vias 234 (e.g., Through Silicon Vias (TSVs) for silicon interposers). The vias 234 can extend vertically and across at least a portion of the thickness of the stacking interposer 220. At the opposing end, the vias 234 can be connected to the bottom RDL 232b, and the bottom RDL 232b can be connected to the bump pads 230 for the bottom-side dies (e.g., the first die 212a for the first interposer 220a and the third die 212c for the second interposer 220b). Thus, the top-side RDL 232a, the vias 234, and the bottom-side RDL 232b can couple the bottom-die first pads 228a and the bottom-die second pads 228b to the bottom-side dies.

The package 200 can include wirebonds that extend the connections to the dies to wirebond pads on the substrate 204 and to circuits external to the dies (e.g., components on the substrate or through external connectors on the substrate). For example, for each interposer, a set of top-die first bondwires 236a can be connected to the top-die first pads 226a, a set of top-die second bondwires 236b can be connected to the top-die second pads 226b, a set of bottom-die first bondwires 238a can be connected to the bottom-die first pads 228a, and a set of bottom-die second bondwires 238b can be connected to the bottom-die second pads 228b. The opposite ends of these bondwires can be attached to corresponding pads on the substrate. Thus, each stacking interposer 220 can have four sets of bond wires-one set of bondwires on the left side for the top-side die, one set of bondwires on the right side for the top-side die, one set of bondwires on the left side for the bottom-side die, and one set of bondwires on the right side for the bottom-side die.

Based on the connections on the opposing sides, the package 200 having the stacking interposers 220 with wirebond pads on opposing sides of the dies can have any maximum lengths correspond to half the lateral dimension of the dies. Moreover, the package 200 can provide the corresponding IR drop (e.g., the voltage drop, especially for power connections) without increasing the overall heights like the second conventional type of package 150 of FIG. 1B. In other words, the back-to-back die attachments (e.g., the backside attachments of second die 212b and the third die 212c) can provide sufficient thickness to accommodate the maximum loop height of the bondwires without the spacers 120 of FIGS. 1A and 170 of FIG. 1B.

Moreover, the package 200 can reduce package height based on reducing the number of interposers, such as from (N−1) interposers to (N/2). Stated differently, the number of layers that needs to be bonded out can be reduced from (N−1) to N/2 (e.g., N=4 for the illustrated example). The reduction in the number of layers for wire bonding can correspond to reducing the overall height associated with wire loop heights.

Further, since the manufacturing cost of the interposers are lower than that of the dies, the lateral connections can be achieved for lower cost in comparison to having the lateral connections within the die. For the same reason, the RDLs 232a and 232b can have physical characteristics, such as thicker/wider traces), that further reduce the IR drop in comparison to having the standard lateral connections within the die. Moreover, in removing the lateral connections, the circuit layout within the dies can be adjusted to allocate the circuits closer to the bump pads on the die. Additionally or alternatively, the removal of the lateral connections can free up the corresponding space for other purposes, such as additional functional circuitry or to simplify the remaining routing paths.

FIG. 2B is a top view of a stacking interposer (e.g., one of the stacking interposers 220) in accordance with embodiments of the technology. As described above, the interposer top side 222 can have wirebond pads on opposing sides for each of the connected dies. The interposer top side 222 can have (1) the top-die first pads 226a and the bottom-die first pads 228a on the left side and (2) the top-die second pads 226b and the bottom-die second pads 228b on the right side. Each set of pads can be arranged linearly on the corresponding peripheral portions of the interposer.

The top-side die can be mounted over a middle portion of the interposer. As illustrated in FIG. 2B, the outline or the footprint of the top-side die is shown using dashed lines. Within the outline, the interposer top side 222 can have the bump pads 230 configured to attach to corresponding pads on the topside die through the die connectors 216 of FIG. 2A.

FIG. 2C is a bottom view of the stacking interposer (e.g., one of the stacking interposers 220) in accordance with embodiments of the technology. Like the interposer top side 222 of FIG. 2B, the interposer bottom side 224 can have the bump pads 230 configured to couple to the bottom-side die. As illustrated in FIG. 2C, the outline or the footprint of the bottom-side die is shown using dashed lines, and the bump pads 230 can be located within the outline. The shape and arrangement of the bump pads 230 can match that of the bump pads on the top side.

As discussed above, the bump pads 230 can be arranged throughout or across the lateral dimensions of the dies. Thus, the internal lateral routing of the signals can be reduced in comparison to dies and packages utilizing edge/peripherally located bondwire pads, such as the conventional types of packages 100 of FIGS. 1A and 150 of FIG. 1B.

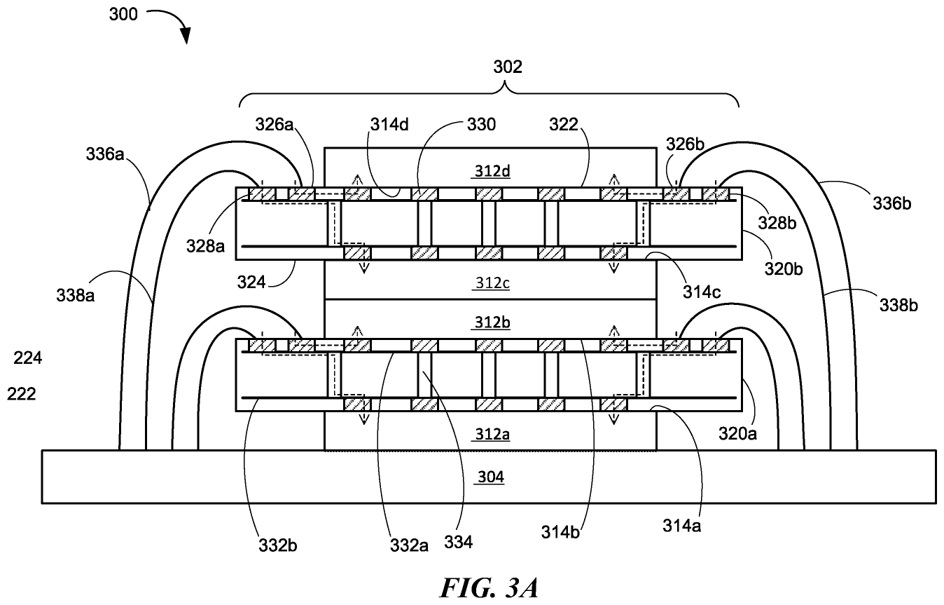

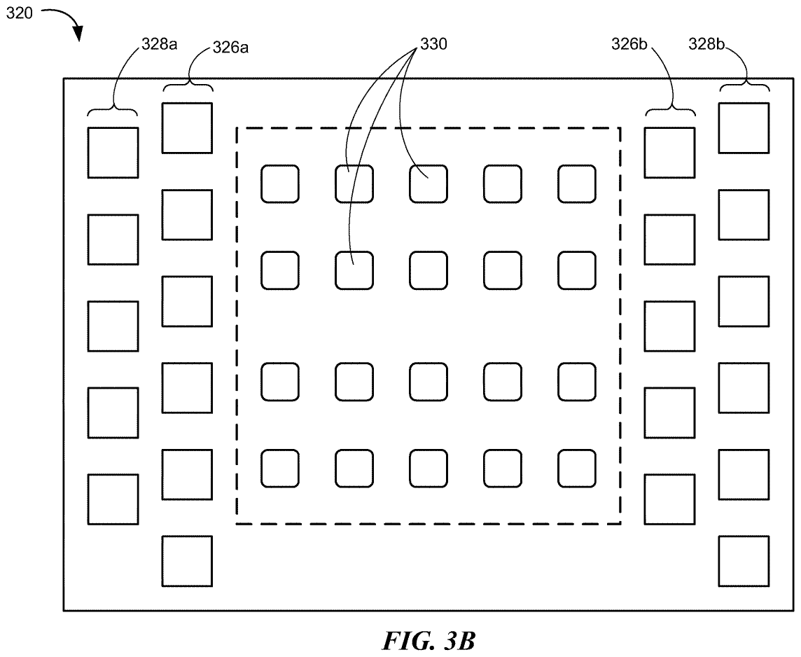

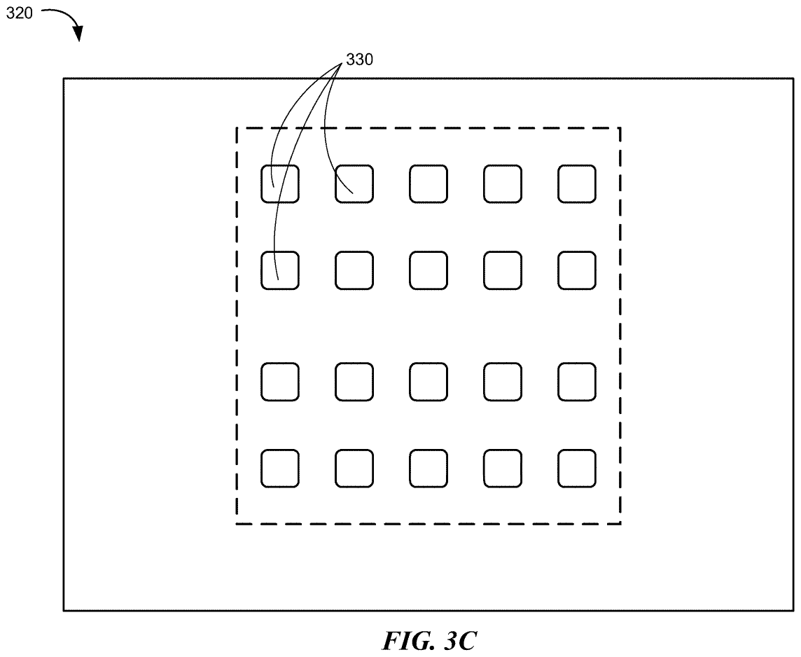

In other embodiments, the stacking interposers can support direct or hybrid bondings with the dies. In other words, the dies and the stacking interposers can have corresponding hybrid bonding pads that can be fused or bonded to each other, thereby both electrically coupling and attaching the pads together without additional structures (e.g., the die connectors 216 of FIG. 2A). To further illustrate an example of such embodiments, FIG. 3A is a cross-sectional view of a second package 300 including stacking interposers 320 in accordance with embodiments of the technology. The second package 300 can be similar to the first package 200 but use direct/hybrid bonding between the dies and the stacking interposers 320.

The second package 300 can include a die stack 302 mounted over a substrate 304. The package 300 can be a four-die package with the die stack 302 including dies 312a-312d. Each of the stacking interposers 320 can be disposed between and attached to active sides of an adjacent or a facing pair of dies. For example, a first stacking interposer 320a can be disposed between and attached to (1) an active side 314a of a first die 312a and (2) an active side 314b of a second die 312b. A backside of the first die 312a can be mounted on the substrate 304. Also, for example, a second stacking interposer 320b can be disposed between and attached to (1) an active side 314c of a third die 312c and (2) an active side 314d of a fourth die 312d. A backside of the second die 312b can be attached to a backside of the third die 312c. The second die 312b and the fourth die 312d can be flipped relative to the first die 312a and the third die 312c. Each of the dies 312a-312d can have hybrid bonding pads on their active sides that are fused or bonded to hybrid bonding pads 330 on the top and bottom sides of the stacking interposers 320.

The structure of the stacking interposers 320 can be similar to that of the stacking interposers 220 of FIG. 2A. For example, each of the stacking interposers 320 can have on its interposer top side 222 (1) a set of top-die first pads 326a, (2) a set of top-die second pads 326b, (3) a set of bottom-die first pads 328a, and (4) a set of bottom-die second pads 328b. These wirebonding pads can be connected to a top-side RDL 332a, a bottom-side RDL 332b, vias 334, or a combination thereof to provide electrical connections to the top-side die and the bottom-side die. Further, these wriebonding pads can be connected to corresponding ones of top-die first bondwires 336a, top-die second bondwires 336b, bottom-die first bondwires 338a, and bottom-die second bondwires 338b.

The stacking interposers 320 can provide the same improvements described above for the stacking interposers 220. Moreover, the package 300 can have a lower overall height than the package 200 of FIG. 2 by using the hybrid bonding scheme and removing the die connectors 216.

FIG. 3B is a top view of a stacking interposer (e.g., the stacking interposers 320) in accordance with embodiments of the technology. Similar to the stacking interposer 220 of FIG. 2, the interposer top side 322 can have wirebond pads on opposing sides for each of the connected dies. The interposer top side 322 can have (1) the top-die first pads 326a and the bottom-die first pads 328a on the left side and (2) the top-die second pads 326b and the bottom-die second pads 328b on the right side. Each set of pads can be arranged linearly on the corresponding peripheral portions of the interposer.

The top-side die can be mounted over a middle portion of the interposer. As illustrated in FIG. 3B, the outline or the footprint of the top-side die is shown using dashed lines. Within the outline, the interposer top side 322 can have the hybird bonding pads 330 configured to directly fuse or bond to corresponding pads on the topside die.

FIG. 3C is a bottom view of the stacking interposer 320 in accordance with embodiments of the technology. The interposer bottom side 324 can have the hybrid bonding pads 330 configured to couple to the bottom-side die. As illustrated in FIG. 3C, the outline or the footprint of the bottom-side die is shown using dashed lines, and the hybrid bonding pads 330 can be located within the outline. The shape and arrangement of the hybrid bonding pads 330 can match that of the pads on the top side.

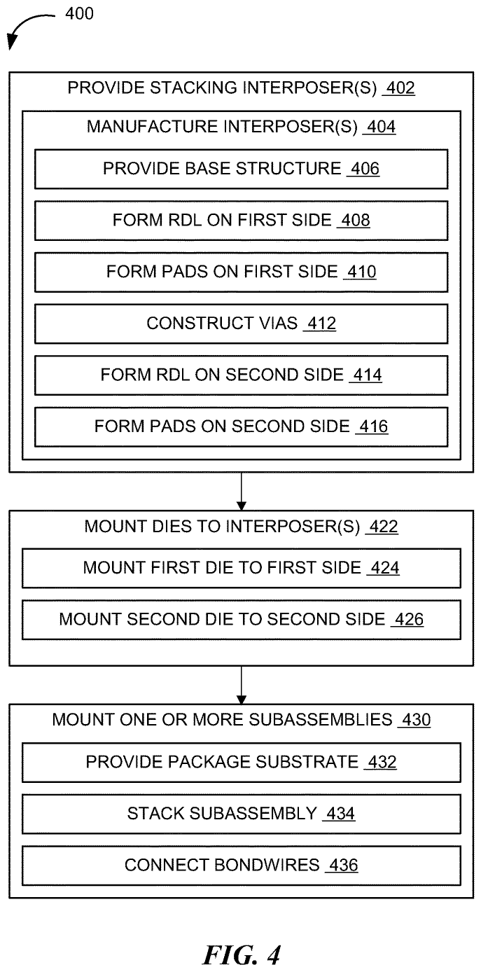

FIG. 4 is a flow diagram illustrating an example method 400 of manufacturing an apparatus (e.g., the stacking interposers 220 of FIG. 2A or 320 of FIG. 3A, the package 200 of FIG. 2A, the package 300 of FIG. 3A, or a combination thereof) in accordance with an embodiment of the present technology. The method 400 can be for manufacturing and/or utilizing the double-sided die attachable stacking interposer as described above.

The method 400 can include, such as illustrated at block 402, providing one or more stacking interposers (e.g., the stacking interposers 220 and/or 320 of FIG. 3A). In some embodiments, providing the stacking interposers can include obtaining, preparing, and/or positioning the stacking interposers for further manufacturing processing.

In other embodiments, providing the stacking interposers can include manufacturing the interposers as shown in block 404. The stacking interposers can be manufactured based on providing a base structure as shown in block 406. For example, the method 400 can include obtaining, preparing, and/or positioning the base structure, such as the semiconductor structure (e.g., wafer), PCB, glass, etc., for subsequent processing. At block 408, the method 400 can include forming an RDL on a first side. The RDL (e.g., the top-side RDL 232a of FIG. 2A, the bottom-side RDL 232b of FIG. 2A, the top-side RDL 332a of FIG. 3A, or the bottom-side RDL 332b of FIG. 3A) can be formed by forming receiving layers, etching/masking to receive and shape conductive material, metallization or depositing electrical conductors, or a combination thereof. Using similar manufacturing processes, the method 400 can include forming pads, such as the bump pads 230 of FIG. 2A and/or the hybrid bonding pads 330 of FIG. 3A, as illustrated at block 410. If the initially exposed first side is the top-side, the method can include forming the wirebond pads (e.g., pads 226a, 226b, 228a, and 228b of FIG. 2A, and/or pads 326a, 326b, 328a, and 328b of FIG. 3A) at block 410.

At block 412, the method 400 can include constructing vias, such as the vias 234 of FIG. 2A and/or vias 334 of FIG. 3A. The vias can be constructed by masking and then etching depressions across a thickness of the base structure. Electrically conductive material can be deposited within the depressions to construct the vias.

For implementing the processing steps at block 414 and 416, the base structure can be flipped to expose a different surface. On the exposed second surface (e.g., surface opposite the first side), the method 400 can include forming a second RDL (e.g., remaining ones of the top-side RDL 232a, the bottom-side RDL 232b, the top-side RDL 332a, or the bottom-side RDL 332b) after block 408 as shown in block 414. Similarly, the method 400 can include forming pads, such as the bump pads 230 and/or the hybrid bonding pads 330, on the second surface. If the second side corresponds to the top-side, the formed pads can include the wirebond pads.

Using the provided stacking interposers, the method 400 can include constructing sub-assemblies. At block 422, the method 400 can begin constructing the sub-assemblies by mounting dies to each stacking interposer. At block 424, the method 400 can include mounting a first die to the first side of the provided base structure. At block 426, the method 400 can include mounting a second die to the second side. The dies can be mounted based on positioning the dies and then reflowing solder or by directly bonding the pads on the interposers and the dies. In some embodiments, the first die can be bonded before the interposer is flipped and before the second-side processing begins.

The method 400 can mount the one or more assemblies, as shown in block 430, to manufacture the packages 200 and/or 300. The assembly stacking can begin by providing a package substrate (e.g., the substrate 204 of FIG. 2A and/or the substrate 304 of FIG. 3A) as shown in block 432. The package substrate can be obtained, positioned, and/or prepared for the subsequent processes. At block 434, the method 400 can include stacking the subassembly to an existing structure. For example, the first assembly can be mounted directly on the package substrate. Subsequent assemblies can be mounted on a top-side die of the top-most sub-assembly. In mounting the sub-assemblies, the die on the bottom-side thereof can be directly attached, such as using adhesives, to the top surface of the existing structure. At block 436, the method 400 can include attaching bondwires to (1) the wirebonding pads of the attached sub-assembly and (2) corresponding pads on the package substrate. The processes described for blocks 434 and 436 can be repeated until a targeted number of subassemblies (e.g., the targeted number of dies) are stacked to form the die stack 302 of FIG. 3A or the die stack 202 of FIG. 2A.

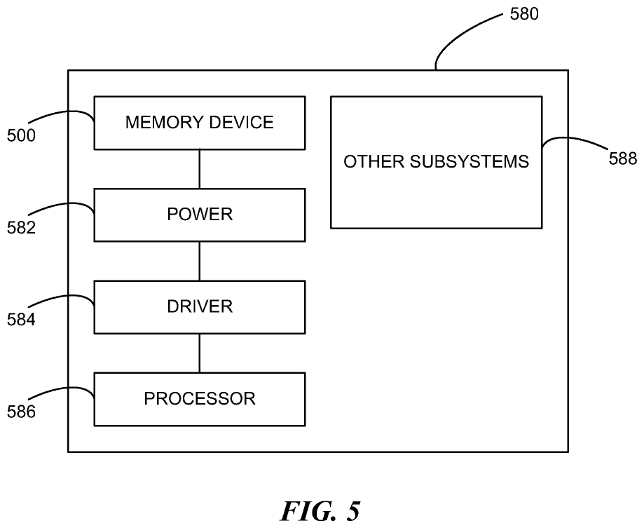

FIG. 5 is a schematic view of a system that includes an apparatus in accordance with embodiments of the present technology. Any one of the semiconductor devices described above with reference to FIGS. 2A-4 can be incorporated into any of a myriad of larger and/or more complex systems, a representative example of which is system 590 shown schematically in FIG. 5. The system 590 can include a semiconductor device 500 (“device 500”) (e.g., a semiconductor device, package, and/or assembly), a power source 592, a driver 594, a processor 596, and/or other subsystems or components 598. The device 500 can include features generally similar to those devices described above. The resulting system 590 can perform any of a wide variety of functions, such as memory storage, data processing, and/or other suitable functions. Accordingly, representative systems 590 can include, without limitation, hand-held devices (e.g., mobile phones, tablets, digital readers, and digital audio players), computers, and appliances. Components of the system 590 may be housed in a single unit or distributed over multiple, interconnected units (e.g., through a communications network). The components of the system 590 can also include remote devices and any of a wide variety of computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” and “having” are used throughout to mean including at least the recited feature(s) such that any greater number of the same feature and/or additional types of other features are not precluded. Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

What is claimed is:

1. A semiconductor package, comprising:
a package substrate;
a first memory die attached over the package substrate, the first memory die having a first input;
a second memory die attached over the substrate, the second memory die having a second input;
an interposer disposed between and attached to the first and second memory dies,
wherein the first memory die is attached to a bottom surface of the interposer and the second memory die is attached to a top surface of the interposer,
the interposer having:
(1) a first interposer connector on the bottom surface and coupled to the first input of the first memory die,
(2) a second interposer connector on the top surface and coupled to the second input of the second memory die,
(3) a first wirebond pad on the top surface,
(4) a second wirebond pad on the top surface,
(5) a first internal connection coupling the first wirebond pad to the first interposer connector, and
(6) a second internal connection coupling the second wirebond pad to the second interposer connector;
a first bondwire coupling the first wirebond pad to the package substrate; and
a second bondwire coupling the second wirebond pad to the package substrate.

2. The semiconductor package of claim 1, wherein:
the first and second memory dies each have an active side that faces the interposer; and
the first memory die has a backside that faces downward and toward the package substrate.

3. The semiconductor package of claim 1, wherein the interposer includes at least one via within the second internal connection, wherein the via extends vertically and at least partially through a thickness of the interposer.

4. The semiconductor package of claim 3, wherein:
the first memory die, the second memory die, and the interposer correspond to a first subassembly, wherein the backside of the first memory die is directly attached to a top side of the package substrate;
further comprising:
a second subassembly having a pair of dies each having an active side facing and attached to opposing surfaces of a second interposer, the second interposer having wirebond pads on a top surface of the second interposer and electrically coupled to the pair of dies;
a third bondwire coupling one of the wirebond pads on the second subassembly to the substrate for coupling one of the pair of dies to external circuits; and
a fourth bondwire coupling one of the wirebond pads on the second subassembly to the substrate for coupling other of the pair of dies to the external circuits.

5. The semiconductor package of claim 4, wherein the first and second subassemblies correspond to a die stack that does not include a spacer, wherein the spacer is configured to vertically displace or offset an attached structure without providing an electrical function.

6. The semiconductor package of claim 1, wherein the first and second memory dies are mounted to the interposer through solder bumps or micro bumps.

7. The semiconductor package of claim 1, wherein the first and second memory dies are mounted to the interposer through conductive posts.

8. The semiconductor package of claim 1, wherein:
the first and second interposer connectors are hybrid bonding pads; and
the first and second memory dies are directly bonded to the interposer based on directly attaching the hybrid bonding pads to corresponding pads on the first and second memory dies.

9. The semiconductor package of claim 1, wherein the interposer is a silicon interposer.

10. The semiconductor package of claim 1, wherein the interposer is a substrate interposer.

11. The semiconductor package of claim 1, wherein:
the first and second internal connections include traces extending laterally, the traces having a first physical trait that is different than a corresponding trait of die-internal traces, wherein the first physical trait reduces voltage drop in comparison to the die-internal traces.

12. An apparatus, comprising:
an interposer substrate having a top surface and a bottom surface;
a first set of die pads on the bottom surface and located at a center portion of the interposer substrate, the first die pads configured to connect to a first die;
a second set of die pads on the top surface and located at the center portion of the interposer substrate, the second die pads configured to connect to a second die;
a first wirebond pads on the top surface and coupled to a portion of the first set of die pads; and
a second wirebond pads on the top surface and coupled to a portion of the second set of die pads.

13. The apparatus of claim 12, wherein:
the first wirebond pad is located between the center portion and a first peripheral edge; and
the second wirebond pad is located between the center portion and the first peripheral edge;
the apparatus further comprising:
a third wirebond pad on the top surface and located between the center portion and a second peripheral edge that is opposite the first peripheral edge, the third wirebond pads coupled to a different portion of the first set of die pads; and
a fourth wirebond pad on the top surface and located between the center portion and the second peripheral edge, the fourth wirebond pads coupled to a different portion of the second set of die pads.

14. The apparatus of claim 13, further comprising:
a first die mounted to the bottom surface of the interposer and electrically coupled to the first die pads; and
a second die mounted to the top surface of the interposer and electrically coupled to the second die pads.

15. The apparatus of claim 14, wherein the first and second dies are mounted on and electrically coupled to the interposer through solder material.

16. The apparatus of claim 14, wherein the first and second dies are hybrid bonded to the interposer.

17. The apparatus of claim 14, wherein the first and second dies are both Dynamic Random-Access Memory (DRAM) dies.

18. The apparatus of claim 14, further comprising:
a package substrate having the first die mounted thereon;
a third die attached to the second die, wherein the third die includes a backside attached to the second die and an active side facing upward;
a second interposer having a bottom surface and a top surface, the second interposer having the third die mounted on the bottom surface, the second interposer including wirebonding pads on its top surface;
a fourth die mounted on the top surface of the second interposer, wherein the third and fourth dies are electrically coupled to the wirebonding pads on the top surface of the second interposer; and
bond wires connecting the first, second, third, and fourth wirebond pads of the interposer and the wirebonding pads of the second interposer to corresponding connections on the package substrate.

19. A method of manufacturing an apparatus, the method comprising:
providing an interposer substrate having a first side and a second side opposite the first side;
forming a first redistribution layer (RDL) on the first side of the interposer;
forming first die pads and wirebonding pads on the first side of the interposer, wherein the first die pads are coupled to the first RDL;
constructing vias that extend vertically and at least partially across a thickness of the interposer substrate, wherein the vias are electrically coupled to the first RDL;
forming a second RDL on the second side of the interposer, wherein a portion of the second RDL is coupled to the vias; and
forming second die pads on the second side of the interposer, wherein the second die pads are coupled to a the second RDL.

20. The method of claim 19, further comprising:
constructing a first subassembly based on (1) mounting a first die to the first side of a first interposer and connected to the first die pads and (2) mounting a second die to the second side of the first interposer and connected to the second die pads;
constructing a second subassembly based on (1) mounting a third die to a first side of a second interposer and (2) mounting a fourth die to a second side of the second interposer, wherein the second interposer includes wirebonding pads on the top side;
mounting the first subassembly to a package substrate, wherein a backside of the first die is attached to the package substrate;
forming a first set of bondwires connecting the wirebonding pads of the interposer substrate to corresponding locations on the package substrate;
mounting the second subassembly over the first subassembly, wherein a backside of the third die is attached to a backside of the second die; and
forming a second set of bondwires connecting the wirebonding pads of the second interposer to corresponding locations on the package substrate.
